(19) United States
(12) Patent Application Publication
(10) Pub. No.: US 2017/0179948 A1
(43) Pub. Date: Jun. 22, 2017

(54) SIGNAL TRANSFER CIRCUIT AND CIRCUIT FOR GENERATING HIT SIGNAL INCLUDING THE SAME

(71) Applicant: SK hynix Inc., Gyeonggi-do (KR)

(72) Inventors: Sung-Yub LEE, Gyeonggi-do (KR); Sung-Soo CHI, Gyeonggi-do (KR)

(21) Appl. No.: 15/162,318

(22) Filed: May 23, 2016

(30) Foreign Application Priority Data
Dec. 22, 2015 (KR) 10-2015-0183639

(51) Int. Cl. H03K 17/687

(52) U.S. Cl. CPC H03K 17/6871

(57) ABSTRACT

A signal transfer circuit may include a pass gate coupled between first and second nodes; and a control unit suitable for controlling the pass gate to prevent a current flowing from the second node to the first node during turn-on of the pass gate.

### CROSS-REFERENCE TO RELATED APPLICATION

The present application claims priority of Korean Patent Application No. 10-2015-0183639, filed on Dec. 22, 2015, which is incorporated herein by reference in its entirety.

### BACKGROUND

1. Field

Various embodiments of the present invention relate to a signal transfer circuit and a circuit for generating a hit signal including the same.

2. Description of the Related Art

Hot carrier injection (HCI) may be generated due to voltage difference between drain and source nodes of a MOS transistor. When HCI stress persists, a semiconductor device including the MOS transistor may not operate normally because the characteristics of the MOS transistor are substantially deteriorated.

FIG. 1 is a diagram illustrating the HCI.

Referring now FIG. 1, the MOS transistor N may be supplied with voltages through a drain D, a source S, and a gate G.

When an operating voltage VOP is applied to the gate G, a voltage applied to the drain D sweeps between a ground voltage GND and the operating voltage VOP, and the ground voltage GND is applied to the source S, the MOS transistor N operates in a forward direction F. Operation of the MOS transistor N in the forward direction F means that a current flows from the drain D to the source S. Accordingly, the MOS transistor N is subjected to HCI stress in the forward direction F.

When the operating voltage VOP is applied to the gate G, the ground voltage GND is applied to the drain D, and a voltage applied to the source S sweeps between the ground voltage GND and the operating voltage VOP, the MOS transistor N operates in a reverse direction R. The operation of the MOS transistor N in the reverse direction R means that a current flows from the source S to the drain D.

When the MOS transistor N is subjected to HCI stress in the forward direction F and then operates in the reverse direction R as described above, deterioration of the MOS transistor N may be increased.

### SUMMARY

Various embodiments are directed to a signal transfer circuit and a circuit for generating a hit signal, which are capable of preventing a reverse direction current from flowing into a MOS transistor included in a pass gate.

In an embodiment, a signal transfer circuit may include a pass gate coupled between first and second nodes; and a control unit suitable for controlling the pass gate to prevent a current flowing from the second node to the first node during turn-on of the pass gate.

In an embodiment, a signal transfer circuit may include a first pass gate coupled between first and second nodes, and turned on when a control signal has a first level; a second pass gate coupled between third and fourth nodes, and turned on when the control signal has a second level; a first control unit suitable for pull-down driving the second node when a voltage of the first node is low and a voltage of the second node is high while the control signal has the first level; and a second control unit suitable for pull-down driving the fourth node when a voltage of the third node low and a voltage of the fourth node is high while the control signal has the second level.

In an embodiment, a circuit for generating a hit signal may include an input node to which an address signal is inputted; an output node from which a hit signal is generated; a first signal path comprising: a transfer element coupled between the input node and a first node; and a pass gate coupled between the first node and the output node, and turned on when a fuse signal has a first level; and a second signal path suitable for non-inverting an address signal and transferring the address signal to the output node when the fuse signal has a second level, wherein the first signal path controls the pass gate not to transfer a current from the output node to the first node during turn-on of the pass gate.

### BRIEF DESCRIPTION OF THE DRAWINGS

FIG. 1 is a diagram illustrating a hot carrier injection phenomenon (HCI).

FIG. 2 is a diagram showing the configuration of a signal transfer circuit, according to an embodiment of the present invention.

FIGS. 3A and 3B are diagrams illustrating an operation of the signal transfer circuit of FIG. 2.

FIG. 4 is a waveform diagram illustrating an operation of the signal transfer circuit of FIG. 2.

FIG. 5 is a diagram showing a configuration of a signal transfer circuit, according to an embodiment of the present invention.

FIG. 6 is a diagram showing a configuration of a signal transfer circuit, according to another embodiment of the present invention.

FIG. 7 is a diagram showing a configuration of a signal transfer circuit, according to yet another embodiment of the present invention.

FIG. 8 is a diagram showing a configuration of a circuit for generating a hit signal, according to an embodiment of the present invention.

FIG. 9 is a diagram showing a configuration of a circuit for generating a hit signal, according to another embodiment of the present invention.

FIG. 10 is a diagram showing a memory device including the circuit for generating a hit signal shown in FIG. 8, according to an embodiment of the present invention.

### DETAILED DESCRIPTION

Various embodiments will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the present invention to those skilled in the art. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present disclosure. As used herein, singular forms are intended to include the plural forms as well, unless the context clearly indicates otherwise. It will be further understood that the terms “comprises”, “comprising”, “includes”, and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other instances, well-known process structures and/or processes have not been described in detail in order not to unnecessarily obscure the present disclosure.

In some instances, as would be apparent to one of ordinary skill in the art elements described in connection with a particular embodiment may be used singly or in combination with other embodiments unless otherwise specifically indicated.

Hereinafter, the various embodiments of the present disclosure will be described in detail with reference to the attached drawings.

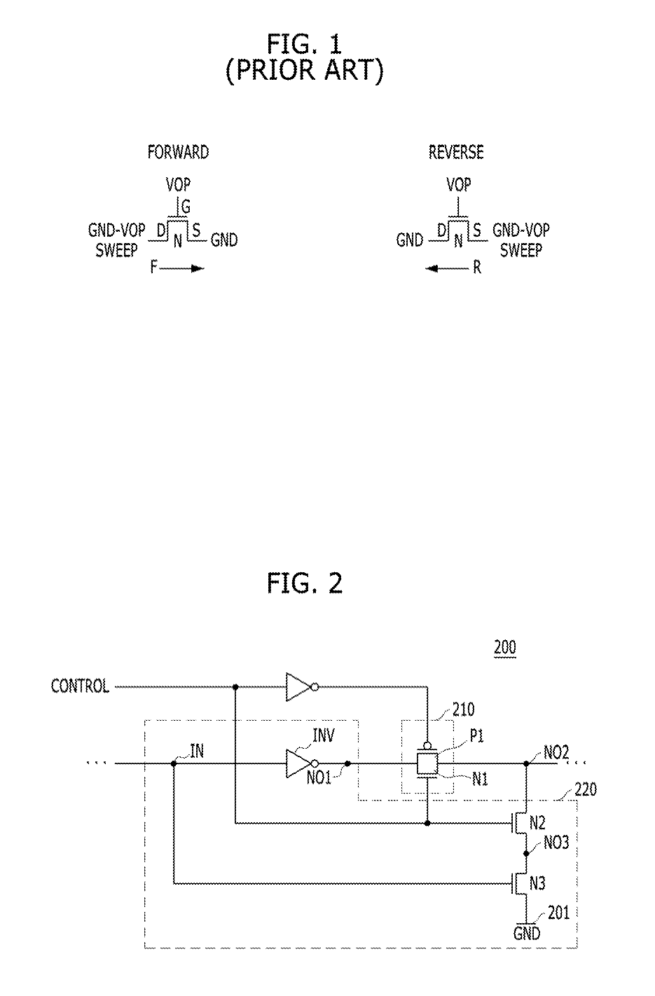

FIG. 2 is a diagram showing a configuration of a signal transfer circuit, according to an embodiment of the present invention.

Referring now to the embodiment illustrated in FIG. 2, the signal transfer circuit is generally designated with numeral 200 and may include a pass gate 210 and a control unit 220.

The pass gate 210 may be coupled between a first node NO1 and a second node NO2. The pass gate 210 may include a MOS transistor N1 coupled between the first node NO1 and the second node NO2 and a PMOS transistor P1 coupled between the first node NO1 and the second node NO2. The pass gate 210 may be turned on when a control signal CONTROL has a high level and may be turned off when the control signal CONTROL has a low level. When the pass gate 210 is turned on, it may electrically couple the first node NO1 and the second node NO2. When the pass gate 210 is turned off, it may electrically separate the first node NO1 and the second node NO2.

The control unit 220 may pull-down drive the second node NO2 when the voltages of the first and second nodes NO1 and NO2 are respectively low and high during the turn-on of the pass gate 210. For such an operation, the control unit 220 may include a MOS transistor N2 turned on or off in response to the control signal CONTROL and coupled between the second node NO2 and a third node NO3, an inverter INV coupled between an input node IN and the first node NO1, and a MOS transistor N3 turned on or off in response to the voltage of the input node IN and configured to have one end coupled to the third node NO3 and to have the other end supplied with a pull-down voltage (e.g., a ground voltage GND).

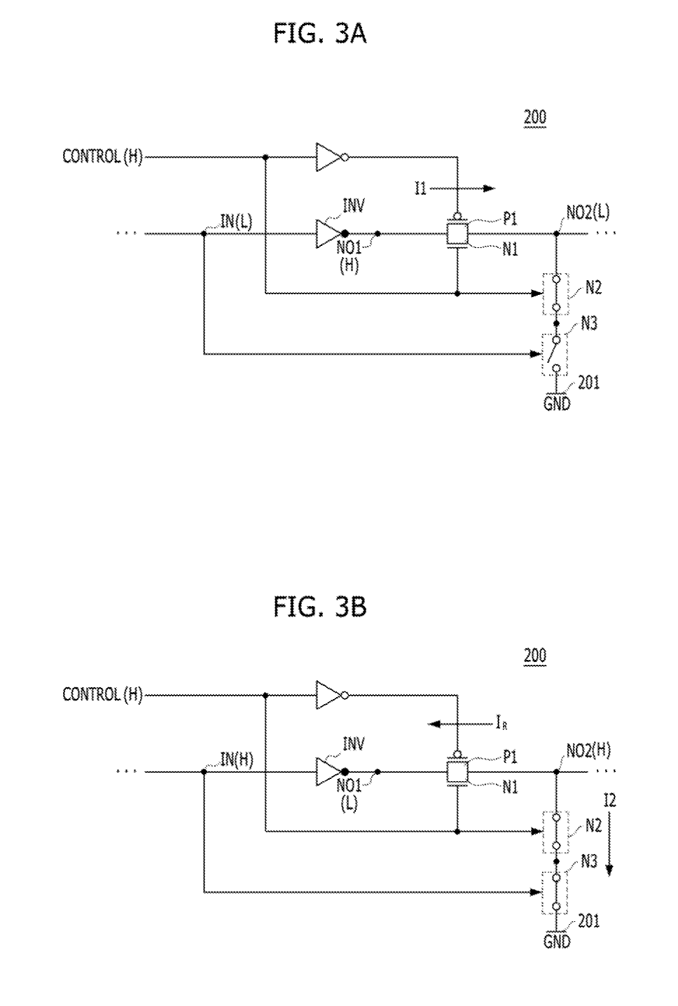

FIGS. 3A and 3B are diagrams illustrating the operation of the signal transfer circuit 200 of FIG. 2.

FIG. 3A is a diagram showing the direction in which a current flows in the signal transfer circuit 200 when the voltages of the first and second nodes NO1 and NO2 are respectively high and low during the turn-on of the pass gate 210. In this case, referring to FIG. 3A, a current I1 flows from the first node NO1 to the second node NO2 (i.e., the forward operation). In this case, the voltage of the first node NO1 may be equalized with the voltage of the second node NO2 by the current flowing from the first node NO1 to the second node NO2.

FIG. 3B is a diagram showing the direction in which a current flows in the signal transfer circuit 200 when the voltages of the first and second nodes NO1 and NO2 are respectively low and high during the turn-on of the pass gate 210. In this case, referring to FIG. 3B, a current may flow from the second node NO2 to the first node NO1. In this case, deterioration of the MOS transistor N1 may increase because the reverse direction operation is performed. In FIG. 2, the control unit 220 of the signal transfer circuit 200 may couple the second node NO2 to a pull-down voltage stage 201 and pull-down drive the second node NO2 for preventing operation in the reverse direction when the voltages of the first and second nodes NO1 and NO2 are respectively low and high. That is, the control unit 220 may control the signal transfer circuit so that a current I2 flows from the second node NO2 to the pull-down voltage stage 201. In this manner, the control unit 220 controls the signal transfer circuit so that a current does not reversely flow from the second node NO2 to the first node NO1.

When the second node NO2 is pull-down driven, the voltage of the second node NO2 becomes the same as the voltage level of the first node NO1 because it becomes a low level. Accordingly, although a reverse direction current I_{R} does not flow, the same effect as if the voltage of the first node NO1 has been transferred to the second node NO2 can be obtained.

For reference, FIGS. 3A and 3B show that each of the MOS transistors N2 and N3 have been illustrated as a switch and the switches have been illustrated as closed when they are turned on and have been illustrated as open when they are turned off.

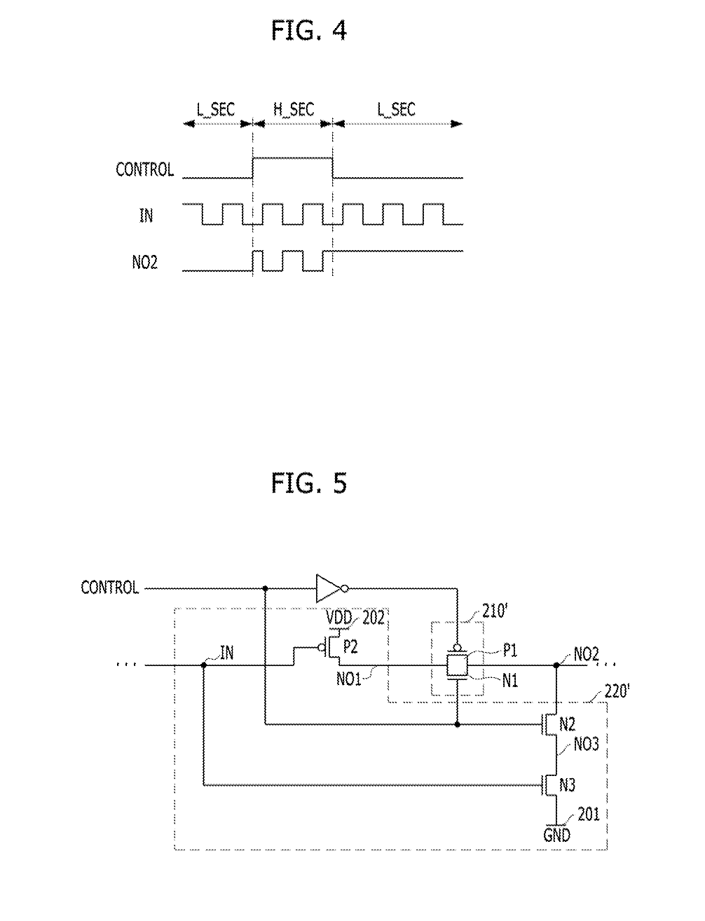

FIG. 4 is a waveform diagram illustrating the operation of the signal transfer circuit 200 of FIG. 2.

According to the embodiment illustrated in FIG. 4, the voltage of the first node NO1 may be transferred to the second node NO2 in a section H_SEC in which the control signal CONTROL has a high level, and the voltage of the first node NO1 may be blocked in a section L_SEC in which the control signal CONTROL has a low level. The voltage of the second node NO2 may be kept to a previous level in the section L_SEC in which the control signal CONTROL has a low level.

According to the embodiment illustrated in FIGS. 2 to 4, the signal transfer circuit may function to prevent the MOS transistor N1 of the pass gate 210 from operating in the reverse direction and to pass a signal only in a specific section as in the conventional pass gate 210.

FIG. 5 is a diagram showing the configuration of a signal transfer circuit, according to an embodiment of the present invention.

According to the embodiment illustrated in FIG. 5, the signal transfer circuit may include the pass gate 210 and a control unit 220′. The signal transfer circuit of FIG. 5 may be the same as the signal transfer circuit of FIG. 2 except that the signal transfer circuit of FIG. 5 includes a PMOS transistor P2 instead of the inverter INV of FIG. 2. The PMOS transistor P2 may be turned on or off in response to the voltage of the input node IN, may have one end coupled to the first node NO1, and may have the other end supplied with a pull-up voltage (e.g., a power supply voltage VDD). In order for the power supply voltage VDD to be applied, the other end of the PMOS transistor P2 may be coupled to a pull-up voltage stage 202.

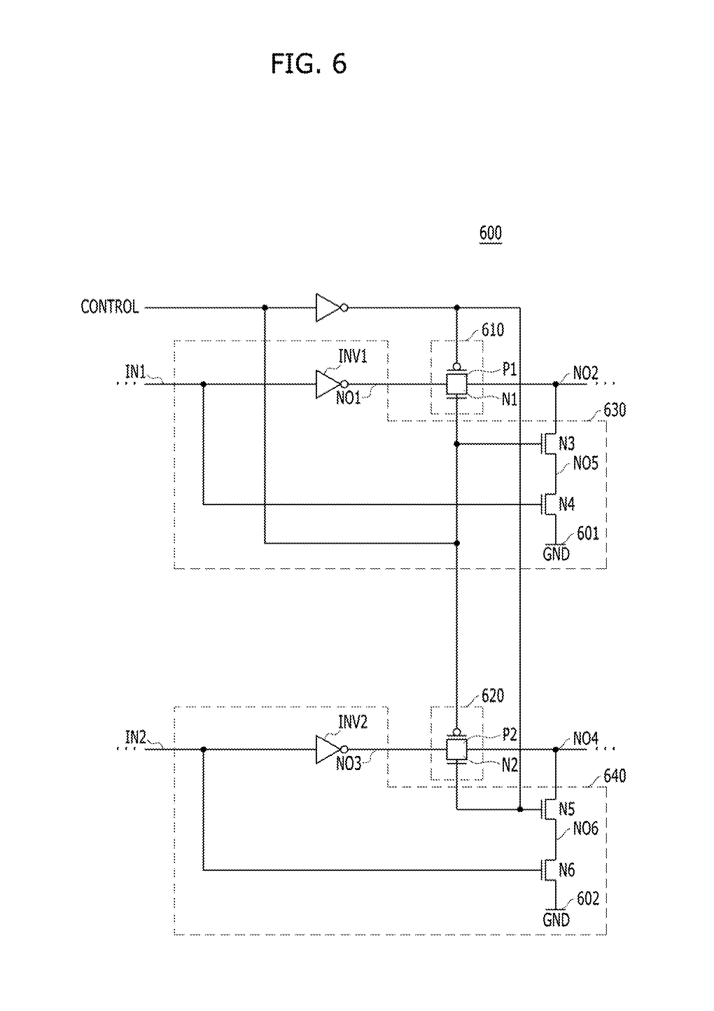

FIG. 6 is a diagram showing the configuration of a signal transfer circuit 600 according to an embodiment of the present invention.

According to the embodiment illustrated in FIG. 6, the signal transfer circuit 600 may include first and second path gates 610 and 620 and first and second control units 630 and 640.

The first pass gate 610 may be turned on when a control signal CONTROL has a first level (e.g., a high level), and the second pass gate 620 may be turned on when the control signal CONTROL has a second level (e.g., a low level). Furthermore, the first pass gate 610 may be turned off when the control signal CONTROL has the second level, and the second pass gate 620 may be turned off when the control signal CONTROL has the first level. The first pass gate 610 may include a MOS transistor N1 and a PMOS transistor P1 coupled between a first node NO1 and a second node NO2. The second pass gate 620 may include a MOS transistor N2 and a PMOS transistor P2 coupled between a third node NO3 and a fourth node NO4.

The first control unit 630 may pull-down drive the second node NO2 when the voltages of the first and second nodes NO1 and NO2 are respectively low and high in the section in which the control signal CONTROL has the first level. For such an operation, the first control unit 630 may include a MOS transistor N3 turned on or off in response to the control signal CONTROL and coupled between the second node NO2 and a fifth node N05, a first inverter INV1 coupled between a first input node IN1 and the first node NO1, and a MOS transistor N4 turned on or off in response to the voltage level of the first input node IN1 and configured to have one end coupled to the fifth node NO5 and to have the other end supplied with a pull-down voltage (e.g., a ground voltage GND). The other end of the MOS transistor N4 may be coupled to a pull-down voltage stage 601.

The second control unit 640 may pull-down drive the fourth node NO4 when the voltages of the third and fourth nodes NO3 and NO4 are respectively low and high in the section in which the control signal CONTROL has the second level. For such an operation, the second control unit 640 may include a MOS transistor N5 turned on or off in response to the control signal CONTROL and coupled between the fourth node NO4 and a sixth node NO6, a second inverter INV2 coupled between a second input node IN2 and the third node NO3, and a MOS transistor N6 turned on or off in response to the voltage level of the second input node IN2 and configured to have one end coupled to the sixth node NO6 and to have the other end supplied with a pull-down voltage (e.g., a ground voltage GND). The MOS transistor N4 may be coupled to a pull-down voltage stage 602 in order to be supplied with the pull-down voltage.

In the signal transfer circuit of FIG. 6, the operations of the pass gates 610 and 620 and the control units 630 and 640 are the same as those of the signal transfer circuit of FIG. 2 except that two input signals are alternately transferred depending on a level of the control signal CONTROL.

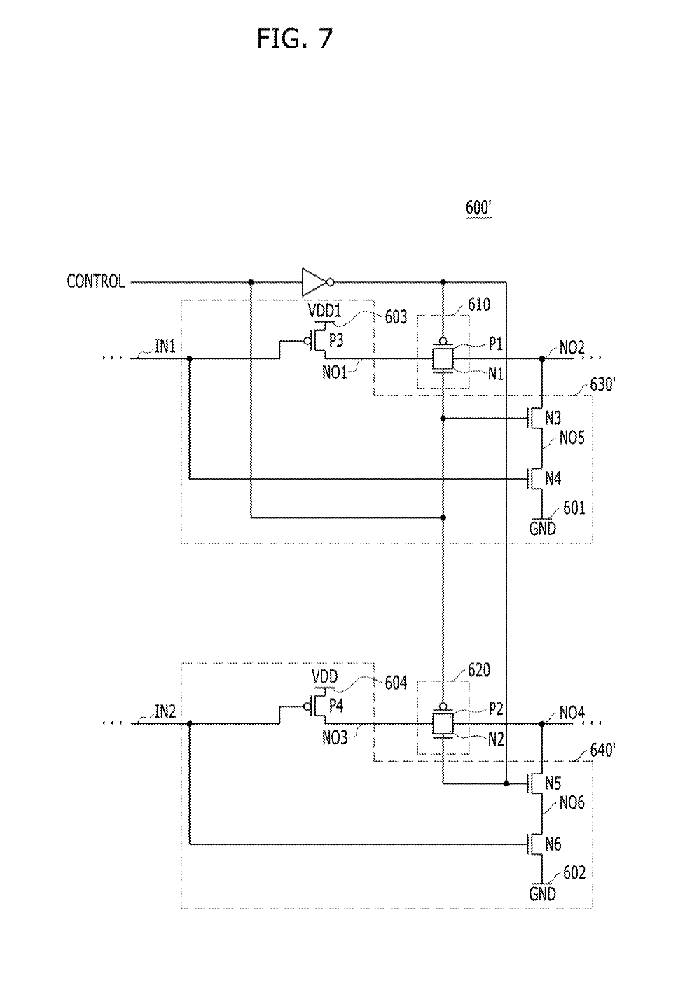

FIG. 7 is a diagram showing the configuration of a signal transfer circuit 600′ according to another embodiment of the present invention.

According to the embodiment illustrated in FIG. 7, the signal transfer circuit 600′ may include the first and second path gates 610 and 620 and first and second control units 630′ and 640′. The signal transfer circuit of FIG. 7 may be the same as the signal transfer circuit of FIG. 6 except that the signal transfer circuit 600′ of FIG. 7 includes PMOS transistors P3 and P4 instead of the inverters INV1 and INV2 of FIG. 6. The operation of the signal transfer circuit of FIG. 7 may be the same as that of the signal transfer circuit of FIG. 6. The PMOS transistors P3 and P4 may have one of their respective ends coupled to respective pull-up voltage stages 603 and 604.

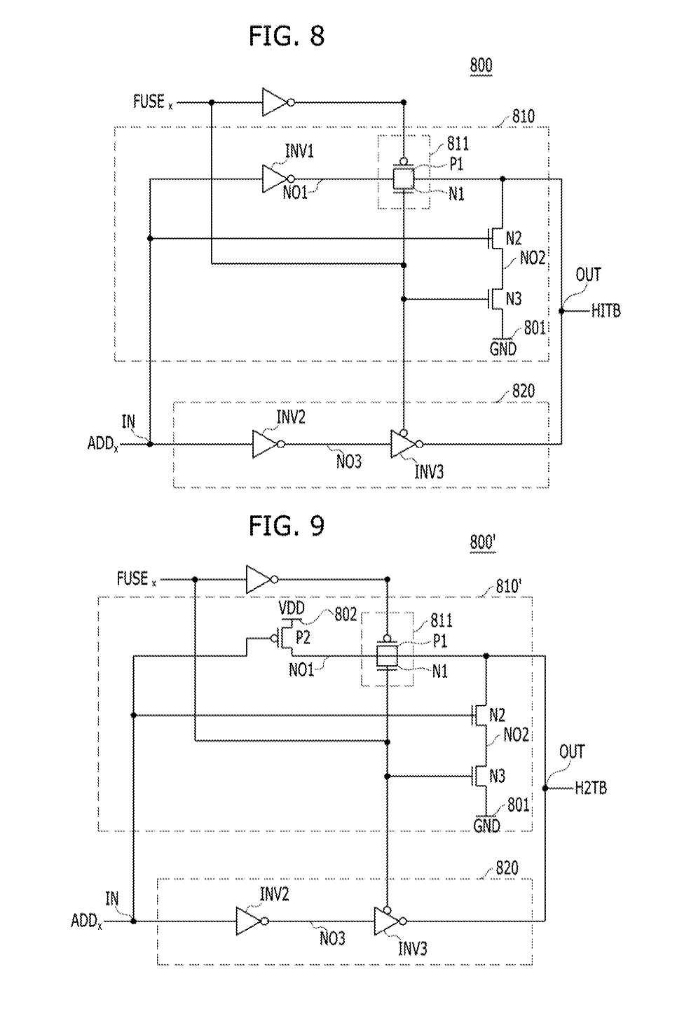

FIG. 8 is a diagram showing a configuration of a circuit for generating a hit signal 800, according to an embodiment of the present invention.

According to the embodiment illustrated in FIG. 8, the circuit for generating a hit signal 800 may include an input node IN, an output node OUT, a first signal path 810, and a second signal path 820.

The input node IN may be a node to which an address signal ADDx is inputted. The address signal ADDx may be indicative of 1 bit of a multi-bit address information. The output node OUT may be a node from which a hit signal HTTB is generated. The hit signal HITB may be a signal indicative of whether the address signal ADDx and a fuse signal FUSEx are the same. The hit signal may have a low level when the address signal ADDx and the fuse signal FUSEx are the same and may have a high level when the address signal ADDx and the fuse signal FUSEx are not the same. The fuse signal FUSEx may be indicative of 1 bit of a multi-bit fuse information.

The first signal path 810 may invert the address signal ADDx when the fuse signal FUSEx has a first level (e.g., a high level) and transfer the inverted address signal to the output node OUT. In this case, when the hit signal HITB has a high level and the address signal ADDx has a low level, the first signal path 810 may pull-down drive the output node OUT. For such an operation, the first signal path 810 may include a pass gate 811 coupled between a first node NO1 and the output node OUT, a MOS transistor N2 turned on or off in response to the fuse signal FUSEx and coupled between the output node OUT and a second node NO2, an inverter INV1 coupled between the input node IN and the first node NO1, and a MOS transistor N3 turned on or off in response to the address signal ADDx and configured to have one end coupled to the second node NO2 and to have the other end supplied with a pull-down voltage (e.g., a ground voltage GND). The other end of the MOS transistor N3 may be coupled to a pull-down voltage stage 801.

The pass gate 811 may include NMOS and PMOS transistors N1 and P1. The operation of the first signal path 810 is the same as that of the signal transfer circuit of FIG. 2.

The second signal path 820 may non-invert the address signal ADDx when the fuse signal FUSEx has a second level (e.g., a low level) and transfer the non-inverted address signal to the output node OUT. For such an operation, the second signal path 820 may include inverters INV2 and INV3. In this case, when the fuse signal FUSEx has the first level, the inverter INV3 may block a third node NO3 and the output node OUT. When the fuse signal FUSEx has the second level, the inverter INV3 may invert the voltage level of the third node NO3 and output the inverted level to the output node OUT.

An operation of the circuit for generating the hit signal HITB is described below.

When the fuse signal FUSEx has a high level, the address signal ADDx is transferred to the output node OUT through the first signal path 810. In the process of the address signal ADDx being transferred, the level of the address signal ADDx is inverted. Accordingly, the hit signal HITB has an opposite level to the address signal ADDx.

When the fuse signal FUSEx has a low level, the address signal ADDx is transferred to the output node OUT through the second signal path 820. In the process of the address signal ADDx being transferred, the level of the address signal ADDx is non-inverted. Accordingly, the hit signal HITB has the same level as the address signal ADDx.

Accordingly, when the fuse signal FUSEx and the address signal ADDx have the same level, the hit signal HITB has a low level. When the fuse signal FUSEx and the address signal ADDx have different levels, the hit signal HITB has a high level.

FIG. 9 is a diagram showing a configuration of a circuit for generating a hit signal 800′ according to another embodiment of the present invention.

According to the embodiment illustrated in FIG. 9, the circuit for generating a hit signal 800′ may include the input node IN, the output node OUT, a first signal path 810′, and the second signal path 820. The circuit for generating a hit signal 800′ of FIG. 9 may be the same as the circuit for generating a hit signal 800 of FIG. 8 except that the circuit for generating a hit signal 800′ includes a PMOS transistor P2 instead of the inverter INV1 of FIG. 8. Operation of the circuit for generating a hit signal 800′ may be the same as that of the circuit for generating a hit signal shown 800 of FIG. 8. One end of the PMOS transistor P2 may be coupled to a power supply voltage stage 802.

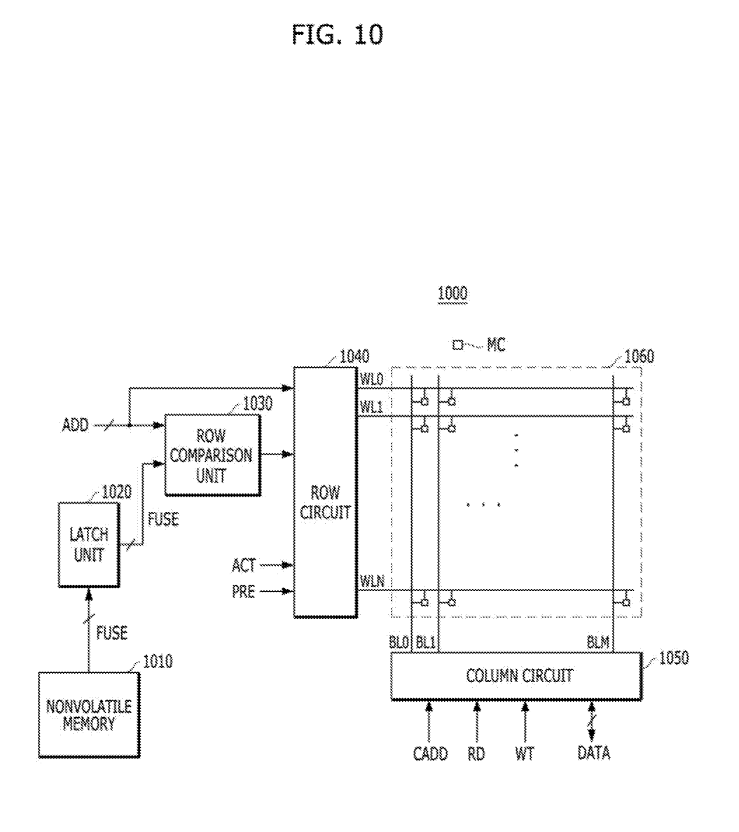

FIG. 10 is a diagram showing a configuration of a memory device 1000 including the circuit for generating a hit signal 800′ shown in FIG. 8.

Referring to FIG. 10, the memory device 1000 may include nonvolatile memory 1010, a latch unit 1020, a row comparison unit 1030, a row circuit 1040, a column circuit 1050, and a memory bank 1060.

The nonvolatile memory 1010 may store fuse information representing address information of a failed memory cell within the memory bank 1050 as repair data FUSE. The nonvolatile memory 1010 may include a fuse cell array. The nonvolatile memory 1010 may store the fuse information or the repair data FUSE in the fuse cell array.

The latch unit 1020 receives and stores the repair data FUSE from the nonvolatile memory 1010. The repair data FUSE stored in the latch unit 1020 may be used for a redundancy operation. The latch unit 1020 includes latch circuits and may store such repair data FUSE only when power is supplied to the memory device. An operation for transferring repair data FUSE from the nonvolatile memory 1010 to the latch unit 1020 and storing the repair data FUSE in the latch unit 1020 is called a boot-up operation. After such a boot-up operation is performed, a redundancy operation is performed using the repair data FUSE stored in the latch unit 1020.

The row circuit 1040 activates a word line selected by address information ADD provided from a device that is external to the memory device 1000. The row comparison unit 1030 compares the repair data FUSE provided from the latch unit 1020 with the address information ADD. When the repair data FUSE is identical with the address information ADD, the row comparison unit 1030 controls the row circuit 1040 to activate a redundancy word line instead of a word line designated by the address information ADD. That is, a row (word line) corresponding to the repair data FUSE provided from the row latch unit 1020 is replaced with a redundancy row (word line). This means that failed memory cells coupled to a normal row are replaced with redundancy cells coupled to a redundancy row.

The number of bits included in the repair data FUSE is the same as the number of bits included in the address information ADD. The row comparison unit 1030 may include the circuit for generating the hit signal 800 shown in FIG. 8 as many times as the number of bits included in the address information ADD. The circuit for generating the hit signal 800 shown in FIG. 8 within the comparison unit 1030 may compare the repair data FUSE with the address information ADD.

The column circuit 1050 may access (i.e., read or write) the data of a bit line selected by the column address CADD. The memory bank 1060 may include a plurality of word lines WL0 to WLN, a plurality of bit lines BL0 to BLM, and memory cells MC coupled between the corresponding word lines and bit lines.

In FIG. 10, an example in which a word line is replaced through the repair data FUSE stored in the nonvolatile memory 1010 has been illustrated, but the repair data FUSE may also be used as data for replacing a column or a memory block.

In FIG. 10, signal ACT is a signal for activating a word line, PRE is a precharge command, RD is a read command, and WT is a write command.

The signal transfer circuit of this technology can prevent the characteristics of a MOS transistor included in a pass gate from being deteriorated by preventing a reverse direction current from flowing into the MOS transistor.

Although various embodiments have been described for illustrative purposes, it will be apparent to those skilled in the art that various changes and modifications may be made without departing from the spirit and/or scope of the invention as defined in the following claims.

What is claimed is:

1. A signal transfer circuit comprising:
a pass gate coupled between first and second nodes; and
a control unit suitable for controlling the pass gate to prevent a current flowing from the second node to the first node during turn-on of the pass gate.

2. The signal transfer circuit of claim 1, wherein the pass gate is turned on when a control signal has a high level, and turned off when the control signal has a low level.

3. The signal transfer circuit of claim 1, wherein the pass gate transfers a current from the first node to the second node when a voltage of the first node is high and a voltage of the second node is low during turn-on of the pass gate.

4. The signal transfer circuit of claim 1, wherein the control unit pull-down drives the second node when a voltage of the first node is low and a voltage of the second node high during turn-on of the pass gate.

5. The signal transfer circuit of claim 1, wherein the control unit comprises:
a first MOS transistor operable in response to a control signal, and coupled between the second node and a third node; and
a second MOS transistor operable in response to a voltage of an input node having an opposite phase of a voltage of the first node, and coupled to the third node at one end and to a pull-down voltage stage at the other end.

6. The signal transfer circuit of claim 5, wherein the control unit further comprises an inverter coupled between the input node and the first node.

7. The signal transfer circuit of claim 5, wherein the control unit further comprises a first PMOS transistor operable in response to the voltage of the input node, and coupled to the first node at one end and to a pull-up voltage stage at the other end.

8. The signal transfer circuit of claim 1, wherein the pass gate comprises:
a MOS transistor coupled between the first and second nodes; and
a PMOS transistor coupled between the first and the second nodes.

9. A signal transfer circuit comprising:
a first pass gate coupled between first and second nodes, and turned on when a control signal has a first level;
a second pass gate coupled between third and fourth nodes, and turned on when the control signal has a second level;
a first control unit suitable for pull-down driving the second node when a voltage of the first node is low and a voltage of the second node is high while the control signal has the first level; and
a second control unit suitable for pull-down driving the fourth node when a voltage of the third node low and a voltage of the fourth node is high while the control signal has the second level.

10. The signal transfer circuit of claim 9, wherein the first control unit comprises:
a first MOS transistor operable in response to the control signal, and coupled between the second node and a fifth node;
a first inverter coupled between a first input node and the first node; and
a second MOS transistor operable in response to a voltage of the first input node, and coupled to the fifth node at one end and to a pull-down voltage stage at the other end.

11. The signal transfer circuit of claim 10, wherein the second control unit comprises:
a third MOS transistor operable in response to the control signal, and coupled between the fourth node and a sixth node;
a second inverter coupled between a second input node and the third node; and
a fourth MOS transistor operable in response to a voltage of the second input node, and coupled to the sixth node at one end and to a pull-down voltage stage at the other end.

12. The signal transfer circuit of claim 9, wherein the first control unit comprises:
a first MOS transistor operable in response to the control signal, and coupled between the second node and a fifth node;
a first PMOS transistor operable in response to a voltage of a first input node, and coupled to the first node at one end and to a pull-up voltage stage at the other end; and
a second MOS transistor operable in response to a voltage of the first input node, and coupled to the fifth node at one end and to a pull-down voltage stage at the other end.

13. The signal transfer circuit of claim 12, wherein the second control unit is suitable for comprising:
a third MOS transistor operable in response to the control signal, and coupled between the fourth node and a sixth node;
a second PMOS transistor operable in response to a voltage of a second input node, and coupled to the third node at one end and to a pull-up voltage at the other end; and
a fourth MOS transistor operable in response to the voltage of the second input node, and coupled to the sixth node at one end and to a pull-down voltage stage at the other end.

14. The signal transfer circuit of claim 9, wherein:
the first pass gate turned off when the control signal has the second level, and
the second pass gate turned off when the control signal has the first level.

15. The signal transfer circuit of claim 9, wherein:
the first pass gate comprises a first MOS transistor coupled between the first and the second nodes, and a first PMOS transistor coupled between the first and the second nodes, and
the second pass gate comprises a second MOS transistor coupled between the third and the fourth nodes, and a second PMOS transistor coupled between the third and the fourth nodes.

16. A circuit for generating a hit signal comprising:
an input node to which an address signal is inputted;
an output node from which a hit signal is generated;
a first signal path comprising:
a transfer element coupled between the input node and a first node; and
a pass gate coupled between the first node and the output node, and turned on when a fuse signal has a first level; and
a second signal path suitable for non-inverting an address signal and transferring the address signal to the output node when the fuse signal has a second level,
wherein the first signal path controls the pass gate not to transfer a current from the output node to the first node during turn-on of the pass gate.

17. The circuit of claim 16, wherein the first signal path pull-down drives the output node when a voltage of the first node is low and a voltage of the output node is high during turn-on of the pass gate.

18. The circuit of claim 16, wherein the first signal path comprises:
a first MOS transistor operable in response to the fuse signal, and coupled between the output node and a second node; and
a second MOS transistor operable in response to the address signal, and coupled to the second node at one end and to a pull-down voltage stage at the other end.

19. The circuit of claim 18, wherein the transfer element comprises an inverter coupled between the input node and the first node.

20. The circuit of claim 18, wherein the transfer element comprises a PMOS transistor operable in response to the address signal, and coupled to the first node at one end and to a pull-up voltage at the other end.
